(19) United States
(12) Patent Application Publication
(10) Pub. No.: US 2008/0266762 A1
(43) Pub. Date: Oct. 30, 2008

(54) Electronic device casing with a plug housing

(75) Inventors: Lien-Hsun Ho, Taipei (TW); Hsiung-Kuei Cheng, Taipei (TW); Han-Yang Huang, Taipei (TW)

Correspondence Address: Joe McKinney Muncy, PO Box 1364, Fairfax, VA, 22038-1364, US

(73) Assignee: CYBER POWER SYSTEM INC.

(21) Appl. No.: 11/790,425

(22) Filed: Apr. 25, 2007

(51) Int. Cl. H05K 7/10

(52) U.S. Cl. 361/679

(57) ABSTRACT

An electronic device casing with a plug housing that has a housing, a plug and a recess. The plug has an electrical wire that connects the plug and the housing, and a connector that electrically connects to the electrical wire through the plug. The recess corresponds to the plug and the connector and has a magnet mounted on the recess where the connector may be stored. When the plug is stored in the recess, the magnet holds the connector. Consequently, the plug can be mounted easily and stably in the recess and removed from the recess without pulling and tugging the electrical wire. Thus the electrical wire will be less likely to have contact faults. Besides, the recess may have a simpler shape that reduces the production cost of the plug housing.

### BACKGROUND OF THE INVENTION

1. Field of the Invention

The present invention relates to an electronic device casing with a plug housing, and especially to an electronic device casing with a plug housing with a magnet.

2. Description of the Prior Art

With the growing popularity of computers and other information devices, many peripheral devices have been developed to support electronic devices. Such peripheral devices include portable storage devices, mice and the like. Although those devices are easy to carry, they have an electrical wire and a plug, which often prove to be cumbersome. Neatly coiling the wire and finding a way to safely store a somewhat bulky plug can be inconvenient. To overcome these shortcomings, casings for some devices have been developed with a fixture to store a plug.

With reference to FIG. 9 and FIG. 10, a conventional electronic device casing with a plug housing comprises a casing (90) and a plug (80).

The casing (90) has a recess (91) and an outer edge. The recess (91) has an inner end, an outer end, an inner surface, a cavity (93) and a slot (92). The cavity (93) is formed in the inner end of the recess (91) and has a slanted guide (94). The slanted guide (94) is an inclined plane and slants toward the inner surface of the recess (91) and has a bottom and a top. The slot (92) is formed in the casing (90) between the outer end of the recess (91) and the outer edge of the casing (90).

The plug (80) connects to an external device, is stored in the recess (91) in the casing (90) and has a proximal end, a distal end, an electrical wire (82) and a connector (81). The electrical wire (82) is connected to the proximal end of the plug, extends through the casing (90), connects to the electronic device and is stored in the slot (92) when the plug (80) is in the recess (91). The connector (81) connects to an external device, is formed in the distal end of the plug (80), is stored in the cavity (93) when the plug (80) is in the recess (91) and may be a Universal Serial Bus (USB). With further reference to FIG. 11, the connector (81) contacts the slanted guide (94) when the connector (81) is inserted into the cavity (93) to guide the connector (81) securely into the cavity (93).

However, the conventional electronic device casing with a plug housing as described has a number of shortcomings. Bending the electrical wire (82) to mount the plug (80) in the recess (91) or pulling the electrical wire (82) to remove the plug (80) from the recess (91) may fatigue or break the electrical wire (82) or cause an electrical short. Furthermore, the slanted guide (94) in the cavity (93) must be formed precisely and cause the production to be intricate and the costs of the electronic device casing with a plug housing to be expensive.

To overcome these shortcomings, the present invention provides an electronic device casing with a plug housing to mitigate or obviate the aforementioned problems.

### SUMMARY OF THE INVENTION

The main objective of the present invention is to provide an electronic device casing with a plug housing that has a housing, a plug and a recess. The plug has an electrical wire that connects the plug and the housing, and a connector that electrically connects to the electrical wire through the plug. The recess corresponds to the plug and the connector and has a magnet mounted on the recess where the connector may be stored. When the plug is stored in the recess, the magnet holds the connector. Consequently, the plug can be mounted easily and stably in the recess and removed from the recess without pulling and tugging the electrical wire. Thus the electrical wire will be less likely to have contact faults. Besides, the recess may have a simpler shape that reduces the production cost of the plug housing.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of an electronic device casing with a plug housing in accordance with the present invention and a plug with the plug removed from the plug housing with features of the plug housing visible through the electronic device casing;

FIG. 2 is a side view in partial section of the electronic device casing in FIG. 1;

FIG. 3 is a top view of the electronic device casing in FIG. 1;

FIG. 4 is a perspective view of the electronic device casing in FIG. 1 with the plug in the plug housing;

FIG. 5 is a side view in partial section of the electronic device casing in FIG. 4;

FIG. 6 is a top view of the electronic device casing in FIG. 4;

FIG. 7 is a side view in partial section of another embodiment of the electronic device casing in FIG. 1;

FIG. 8 is a side view in partial section of another embodiment of the electronic device casing in FIG. 1;

FIG. 9 is an exploded perspective view of a conventional electronic device casing in accordance with the prior art with a plug housing;

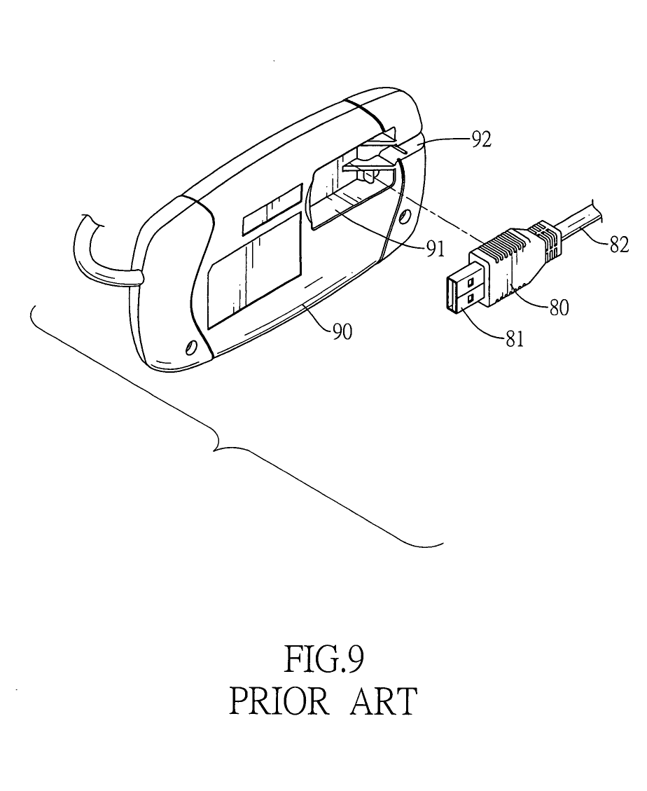

FIG. 10 is a side view in partial section of the electronic device casing in FIG. 7 with a plug in the plug housing; and

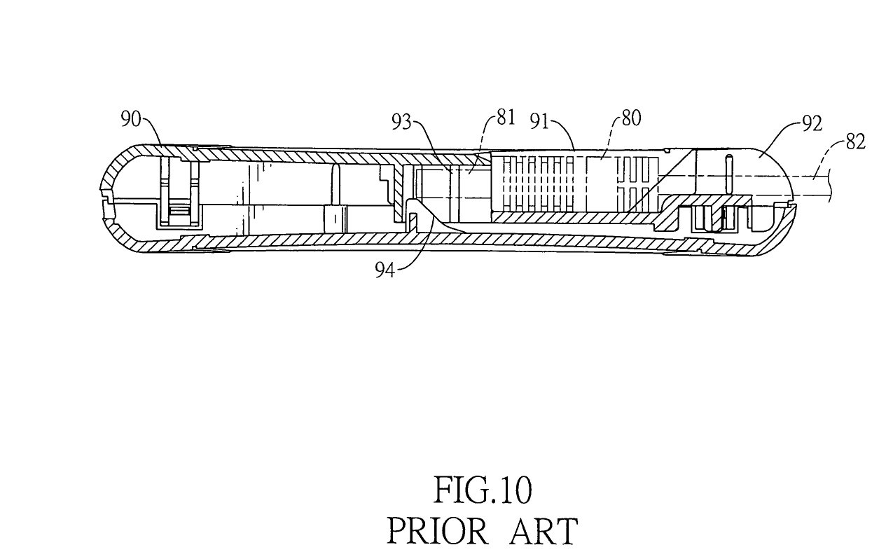

FIG. 11 is an operational side view in partial section of the electronic device casing in FIG. 7 with the plug partially seated in the plug housing.

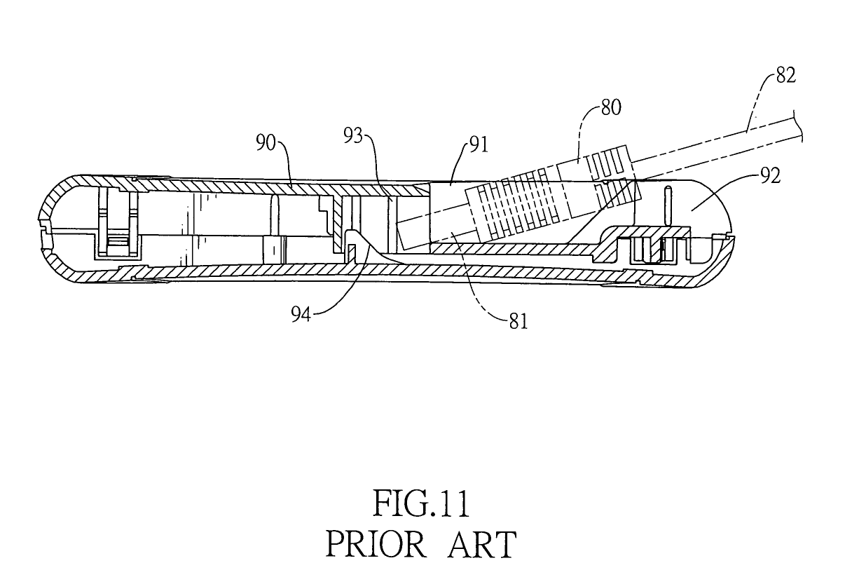

### DETAILED DESCRIPTION OF THE PREFERRED EMBODIMENTS

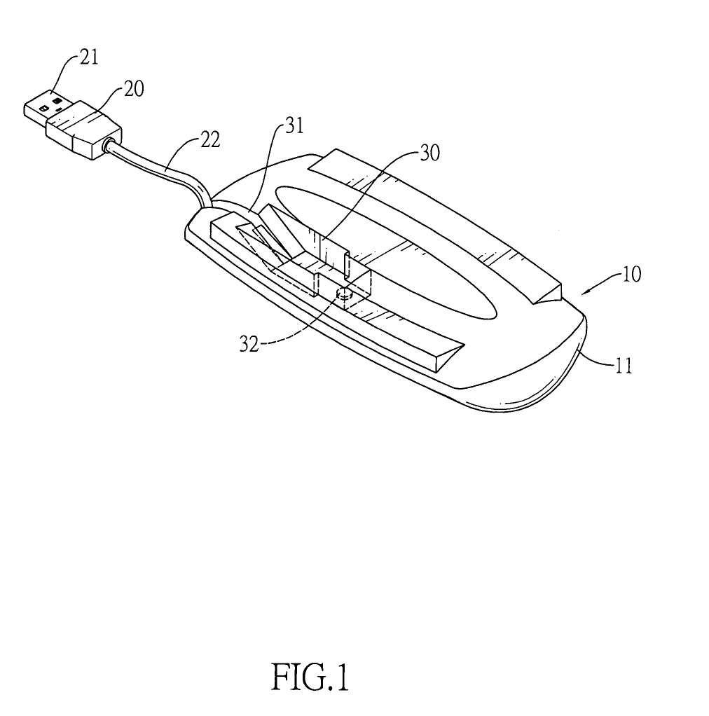

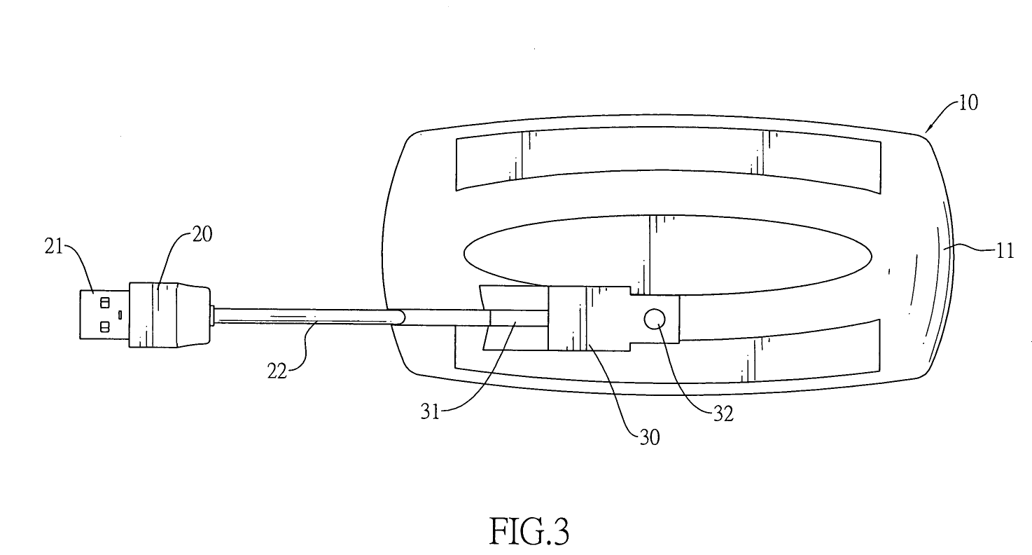

With reference to FIGS. 1 through 3, an electronic device casing with a plug housing in accordance with the present invention comprises a housing (10), a plug (20) and a recess (30).

The housing (10) has a base (12), a cover (11) and a circuit board (13). The cover (11) is mounted on the base (12) and has an outer edge and a proximal end. The circuit board (13) is mounted between the cover (11) and the base (12).

The plug (20) connects to the housing (10) and has a distal end, a proximal end, an electrical wire (22) and a connector (21). The electrical wire (22) is connected to and extends from the proximal end of the plug (20), connects the plug (20) to the circuit board (13) and extends from the proximal end of the cover (11). The connector (21) is formed on and protrudes from the distal end of the plug (20), is electrically connected to the electrical wire (22) through the plug (20), and may be any type of connector for electrically connecting the electronic device to an external electronic device or circuit. For instance, the connector (21) may be a Universal Serial Bus (USB) connector with a metal contact housing. Because the metal contact housing is usually ferrous, the connector (21) is usually attracted to a magnet.

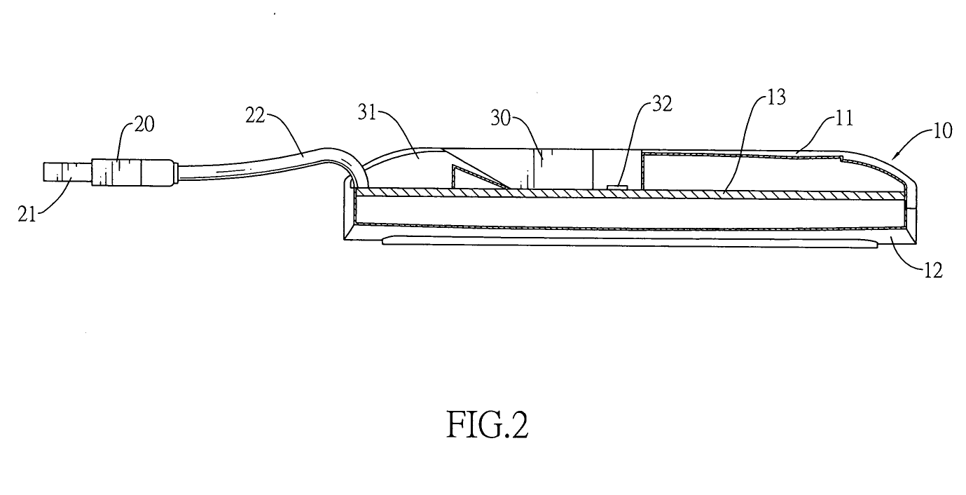

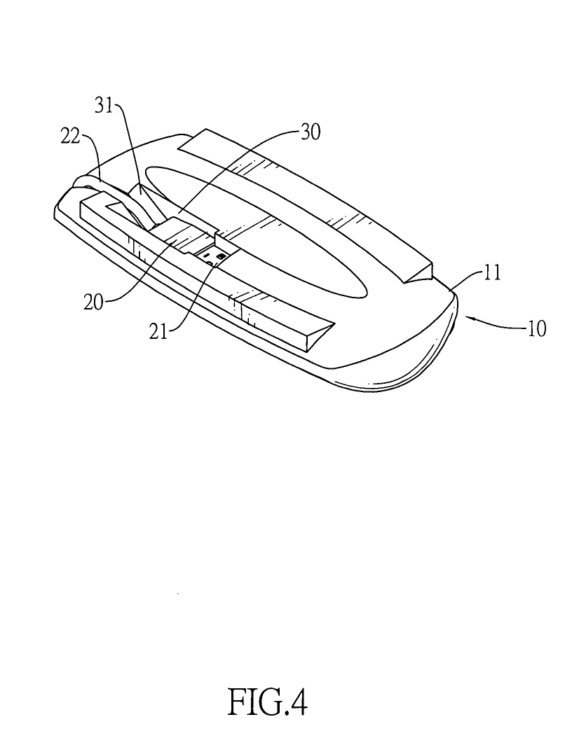

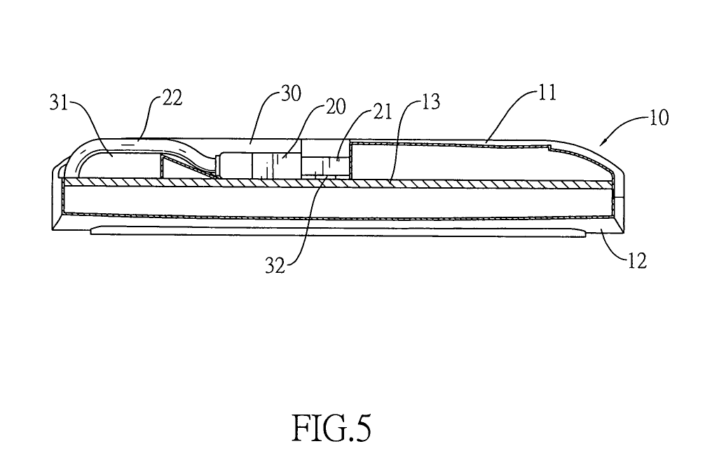

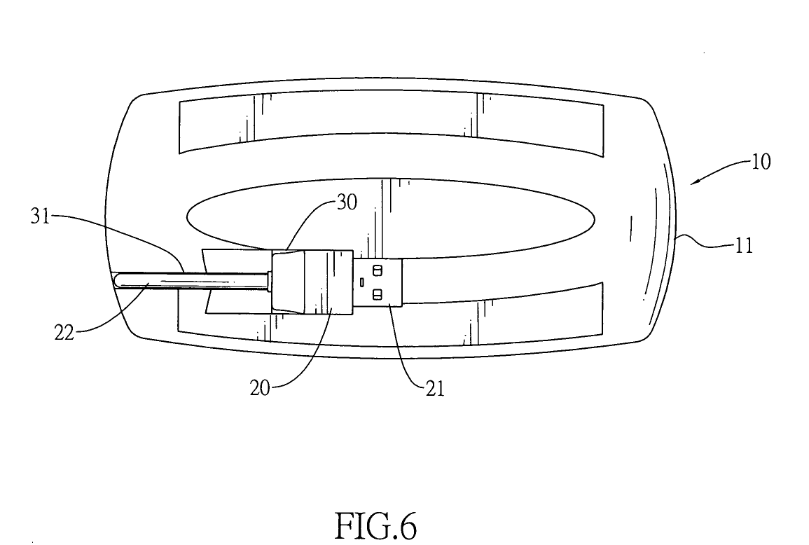

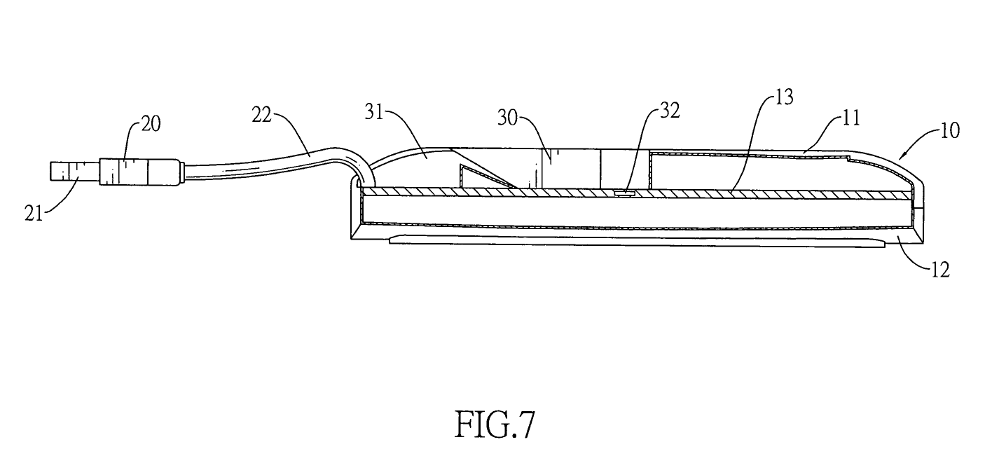

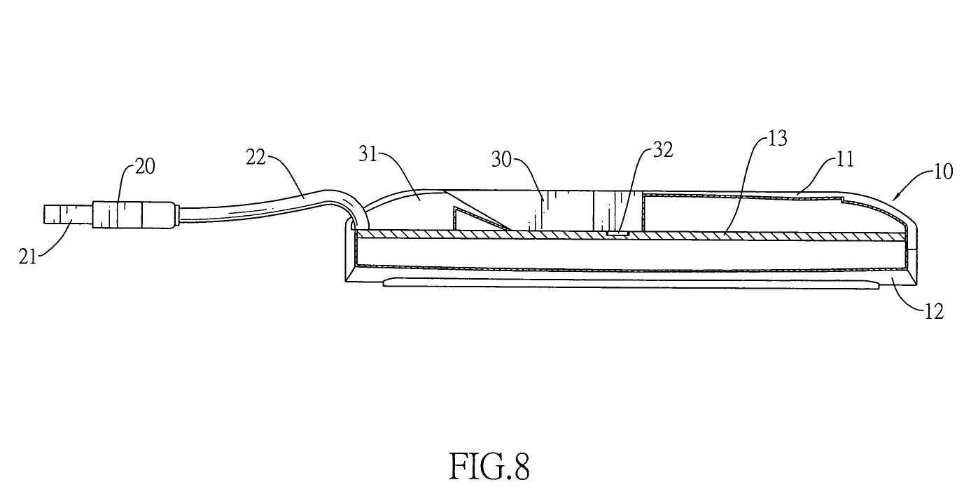

With further reference to FIGS. 4 to 6, the recess (30) is formed in the cover (11) of the housing (10) near the electrical wire (22), corresponds to the plug (20) and the connector (21) and has an inner bottom surface, a slot (31) and a magnet (32). The slot (31) is formed in the cover (11), connects the recess (30) to the outer edge of the cover (11) at the proximal end and holds the electrical wire (22) when the plug (20) is stored in the recess (30). The magnet (32) is mounted on the inner bottom surface of the recess (30) and holds the plug (20) in the recess (30) by connecting magnetically to the metal contact housing on the connector (21). With reference to FIG. 7, the magnet (32) may be mounted under the inner bottom surface of the recess (30), with reference to FIG. 8, embedded in the inner bottom surface of the recess (30) or, with reference to FIG. 2, bonded to the inner bottom surface of the recess (30).

The electronic device casing with a plug housing as described has the following advantages. The recess (30) has a simpler structure since no other indention or protrusion is in the recess (30). Furthermore, the plug (20) may be easily mounted in and removed from the recess (30) with the electrical wire (22) mounted in the slot (31) and the connector (21) held by the magnet (32) in the inner bottom surface of the recess (30). Consequently, no undue force is applied to the electrical wire (22) when mounting the plug (20) in or removing the plug (20) from the recess (30).

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

1. An electronic device casing with a plug housing comprising:
a housing having
a base;
a cover being mounted on the base and having
an outer edge; and
a proximal end; and
a circuit board being mounted between the cover and the base;
a plug connecting to the housing and having
a distal end;
a proximal end;
an electrical wire being connected to and extending from the proximal end of the plug, connecting the plug to the circuit board and extending from the proximal end of the cover; and
a connector being a Universal Serial Bus (USB) connector, being formed on and protruding from the distal end of the plug, being electrically connected to the electrical wire through the plug and having a metal contact housing; and
a recess being formed in the cover near the electrical wire, corresponding to the plug and the connector and having
an inner bottom surface;
a slot being formed in the cover, connecting the recess to the outer edge of the cover at the proximal end; and
a magnet being mounted on the inner bottom surface of the recess and selectively holding the plug in the recess by connecting magnetically to the metal contact housing on the connector.

2. (canceled)

3. The electronic device casing with a plug housing as claimed in claim 1, wherein the magnet is mounted under the inner bottom surface of the recess.

4. The electronic device casing with a plug housing as claimed in claim 1, wherein the magnet is embedded in the inner bottom surface of the recess.

5. The electronic device casing with a plug housing as claimed in claim 1, wherein the magnet is bonded to the inner bottom surface of the recess.

6. The electronic device casing with a plug housing as claimed in claim 1, wherein the magnet on the inner bottom surface of the recess is the only magnet and the plug being without a magnet such that the magnet on the inner bottom surface of the recess attracts the metal contact housing.

7. The electronic device casing with a plug housing as claimed in claim 1, wherein the magnet directly contacts the metal contact housing.

8. An electronic device casing with a plug housing comprising:
a housing having
a base;
a cover being mounted on the base and having
an outer edge; and
a proximal end; and
a circuit board being mounted between the cover and the base;
a plug connecting to the housing and having
a distal end;
a proximal end;
an electrical wire being connected to and extending from the proximal end of the plug, connecting the plug to the circuit board and extending from the proximal end of the cover; and
a connector being a Universal Serial Bus (USB) connector, being formed on and protruding from the distal end of the plug, being electrically connected to the electrical wire through the plug and having a metal contact housing; and
a recess being formed in the cover near the electrical wire, corresponding to the plug and the connector and having
an inner bottom surface;
a slot being formed in the cover, connecting the recess to the outer edge of the cover at the proximal end; and
a magnet being mounted on one of the inner bottom surface of the recess and the plug and the other of the inner bottom surface and plug having a metal face which contacts the magnet whereby the plug is selectively held in the recess by magnetically connecting the magnet and the metal face.

9. The electronic device casing with a plug housing as claimed in claim 8, wherein the magnet is mounted under the inner bottom surface of the recess.

10. The electronic device casing with a plug housing as claimed in claim 8, wherein the magnet is embedded in the inner bottom surface of the recess.

11. The electronic device casing with a plug housing as claimed in claim 8, wherein the magnet is bonded to the inner bottom surface of the recess.

12. The electronic device casing with a plug housing as claimed in claim 8, wherein the magnet is on the inner bottom surface of the recess and is the only magnet and wherein the plug is without a magnet and has a metal contact housing with the metal face such that the magnet on the inner bottom surface of the recess attracts the metal contact housing.

13. The electronic device casing with a plug housing as claimed in claim 8, wherein the magnet directly contacts the metal contact housing.
